(19) United States
(12) Patent Application Publication
(10) Pub. No.: US 2026/0247995 A1
(43) Pub. Date: Aug. 20, 2026

(54) SEMICONDUCTOR MODULE

(71) Applicant: FUJI ELECTRIC CO., LTD., Kawasaki-shi (JP)

(72) Inventor: Ryo MAETA, Matsumoto-shi (JP)

(73) Assignee: FUJI ELECTRIC CO., LTD., Kawasaki-shi (JP)

(21) Appl. No.: 19/439,141

(22) Filed: Jan. 2, 2026

(30) Foreign Application Priority Data
Feb. 14, 2025 (JP) 2025-022084

(51) Int. Cl. H10W 70/40; H10W 90/10

(52) U.S. Cl. CPC H10W 70/468; H10W 70/481; H10W 90/10

(57) ABSTRACT

A semiconductor module includes: one lead frame; a plurality of leads; a plurality of semiconductor chips; and an insulating substrate including a wiring layer. The plurality of semiconductor chips includes at least a first and a second semiconductor chip, each include a first and a second main electrode provided on their first and second main surfaces. A first main surface of the insulating substrate faces the lead frame, and a second main surface of the insulating substrate includes the wiring layer provided thereon. The first main electrode of the first semiconductor chip is electrically connected to the lead frame. The first main electrode of the second semiconductor chip is electrically connected to the wiring layer. A first wiring electrically connecting the second main electrode of the first semiconductor chip and a first lead of the plurality of leads to each other is provided.

### CROSS-REFERENCE TO RELATED APPLICATION(S)

This application is based on and claims priority under 35 USC 119 from Japanese Patent Application No. 2025-022084 filed on Feb. 14, 2025, the contents of which are incorporated herein by reference.

### TECHNICAL FIELD

An embodiment of the present invention relates to a package of a power semiconductor, and more particularly, to a three-level power conversion device.

### BACKGROUND ART

Three-phase inverters used in energy storage systems, uninterruptible power systems (UPS), and motor drives are mainly configured as three-level inverters for high efficiency. There are two types of three-level inverters: I-type and T-type. The I-type is advantageous over the T-type in terms of cost since it can use low breakdown voltage devices; however, it requires an increased number of devices, resulting in a more complex circuit configuration. For this reason, an approach of integrating a plurality of devices constituting the I-type into a single unit has been performed (JP2017-112746A, JP6858244B, and JP7081724B). However, JP2017-112746A, JP6858244B, and JP7081724B do not assume operation in a TO (Transistor Outline) package. The TO package is a package developed for transistors and is widely used mainly for discrete devices. It is used to protect semiconductor chips with resin and to facilitate mounting on printed circuit boards or the like.

### SUMMARY

An object is to provide a semiconductor module in which a plurality of semiconductor chips can be arranged within a TO package.

A semiconductor module according to the present invention is characterized in that it includes a plurality of semiconductor chips arranged, and at least one of the semiconductor chips is provided on a lead frame with an insulating substrate interposed therebetween.

According to the present invention, a semiconductor module in which a plurality of semiconductor chips can be arranged within a TO package can be provided.

### BRIEF DESCRIPTION OF DRAWINGS

FIG. 1 is a circuit diagram of a power conversion device 1 according to the present invention.

FIG. 2A is a circuit diagram of a semiconductor module 100 according to Embodiment 1 of the present invention.

FIG. 2B is a plan view illustrating a configuration of the semiconductor module 100 according to Embodiment 1 of the present invention.

FIG. 2C is a cross-sectional view of the semiconductor module 100 of FIG. 2B, taken along line a-a′.

FIG. 2D is a cross-sectional view of the semiconductor module 100 of FIG. 2B, taken along line a-a′.

FIG. 3A is a circuit diagram of a semiconductor module 200 according to Embodiment 2 of the present invention.

FIG. 3B is a plan view illustrating a configuration of the semiconductor module 200 according to Embodiment 2 of the present invention.

FIG. 4A is a circuit diagram of a semiconductor module 300 according to Embodiment 3 of the present invention.

FIG. 4B is a plan view illustrating a configuration of the semiconductor module 300 according to Embodiment 3 of the present invention.

FIG. 5 is a plan view illustrating a configuration of a semiconductor module according to Modification 1-1 of Embodiment 1 of the present invention.

FIG. 6 is a plan view illustrating a configuration of a semiconductor module according to Modification 1-2 of Embodiment 1 of the present invention.

FIG. 7 is a plan view illustrating a configuration of a semiconductor module according to Modification 2-1 of Embodiment 2 of the present invention.

FIG. 8 is a plan view illustrating a configuration of a semiconductor module according to Modification 2-2 of Embodiment 2 of the present invention.

FIG. 9 is a plan view illustrating a configuration of a semiconductor module according to Modification 3 of Embodiment 3 of the present invention.

FIG. 10A is a circuit diagram of a semiconductor module 400 of the power conversion device 1.

FIG. 10B is a plan view illustrating a configuration of the semiconductor module 400 of the power conversion device 1.

FIG. 11A is a circuit diagram of a semiconductor module 500 of the power conversion device 1.

FIG. 11B is a plan view illustrating a configuration of the semiconductor module 500 of the power conversion device 1.

FIG. 12A is a circuit diagram illustrating combination 1 of semiconductor modules constituting the power conversion device 1.

FIG. 12B is a schematic diagram of the semiconductor modules corresponding to FIG. 12A.

FIG. 13A is a circuit diagram illustrating combination 2 of semiconductor modules constituting the power conversion device 1.

FIG. 13B is a schematic diagram of the semiconductor modules corresponding to FIG. 13A.

FIG. 14A is a circuit diagram illustrating combination 3 of semiconductor modules constituting the power conversion device 1.

FIG. 14B is a schematic diagram of the semiconductor modules corresponding to FIG. 14A.

FIG. 15A is a circuit diagram illustrating combination 4 of semiconductor modules constituting the power conversion device 1.

FIG. 15B is a schematic diagram of the semiconductor modules corresponding to FIG. 15A.

### DESCRIPTION OF EMBODIMENTS

Hereinafter, embodiments for carrying out the present invention will be described with reference to the drawings, but the following embodiments do not limit the invention according to the claims. In addition, not all the combinations of features described in the embodiments are necessarily required in solutions of the invention.

In the specification, a case where a term such as “same” or “equal” is mentioned may include an error due to a variation in manufacturing or the like. The error is, for example, within 10%.

In the specification, one side in a direction parallel to a thickness direction of a lead frame is referred to as “upper”, and the other side is referred to as “lower.” An “upper” direction and a “lower” direction are not limited to a direction of gravity or to a direction when a semiconductor module is mounted on a substrate or the like.

Although types of switches and diodes may be enumerated in the specification, in the circuit diagrams of the drawings, the switches and the diodes are represented by general electrical symbols of an IGBT and a semiconductor diode, respectively, in order to simplify the description.

Materials for parts constituting the semiconductor module may be enumerated, but parts having the same name, regardless of reference signs, may be made of similar materials or may have similar shapes.

### Power Conversion Device

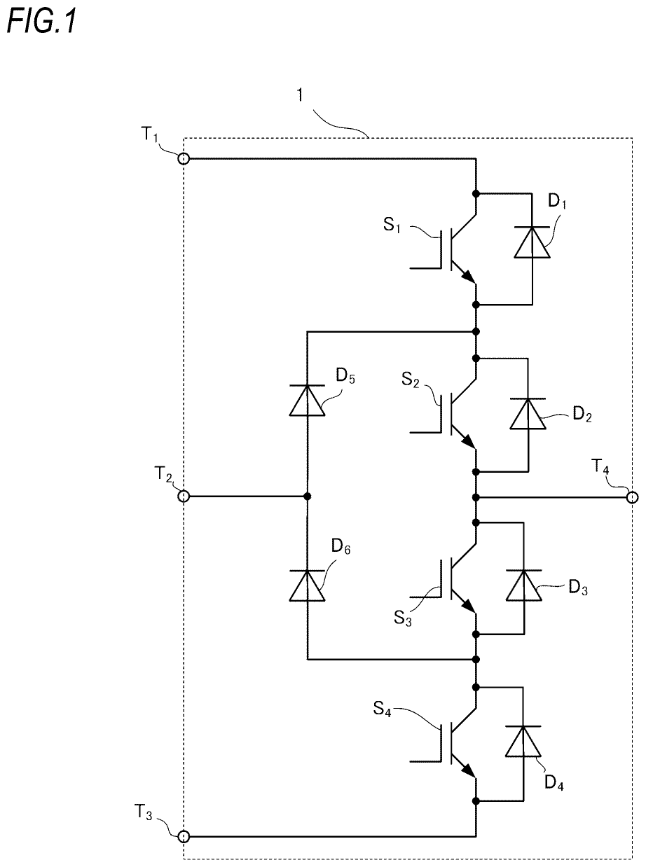

FIG. 1 is a circuit diagram of a power conversion device 1 according to the present invention. S₁ to S₄ are switches. D₁ to D₆ are diodes. T₁ to T₄ are terminals that connect to external circuits. A low-potential-side terminal of a switch Sₘ (m is any natural number equal to or less than 3) and a high-potential-side terminal of a switch Sₘ₊₁ are connected to each other. The diodes D₁ to D₄ are connected in reverse parallel to the switches S₁ to S₄, respectively. That is, the respective low-potential-side terminals of the switches S₁ to S₄ are connected to the respective anode terminals of the diodes D₁ to D₄, and the respective high-potential-side terminals of the switches S₁ to S₄ are connected to the respective cathode terminals of the diodes D₁ to D₄. A connection point between the switch S₂ and the switch S₃ is connected to the terminal T₄. The high-potential-side terminal of the switch S₁ is connected to the terminal T₁, and the low-potential-side terminal of the switch S₄ is connected to the terminal T₃. The diode D₅ and the diode D₆ are connected in series between a connection point between the switches S₁ and S₂ and a connection point between the switches S₃ and S₄, and a connection point between the diode D₅ and the diode D₆ is connected to the terminal T₂. In addition, a cathode of the diode D₅ is connected to the connection point between the switch S₁ and the switch S₂, an anode of the diode D₆ is connected to the connection point between the switch S₃ and the switch S₄, and an anode of the diode D₅ and a cathode of the diode D₆ are connected to the connection point between the diode D₅ and the diode D₆.

The three-level inverter as described above, which has four switches connected in series, is referred to as an I-type.

An operation of this circuit will be described. A constant voltage is applied between the terminal T₁ and the terminal T₂ and between the terminal T₂ and the terminal T₃ by an external circuit. For example, a voltage of 600 V is applied. In this case, 1200 V is applied between the terminal T₁ and the terminal T₃. The terminal T₃ is grounded, for example. By turning on the switch S₁ and the switch S₂ and turning off the switch S₃ and the switch S₄, the potential of the terminal T₄ becomes 1200 V, which is substantially the same as the potential of the terminal T₁. Actually, the potentials of the terminal T₄ and the terminal T₁ are different due to a voltage drop caused by resistance of a switch, a diode, or the like, but since the voltage drop is very small compared to 600 V applied between the terminals, the potential of the terminal T₄ becomes substantially the same as the potential of the terminal T₁. The same expression is used hereinafter for the same reason. By turning on the switch S₂ and the switch S₃ and turning off the switch S₁ and the switch S₄, the potential of the terminal T₄ becomes 600 V, which is substantially the same as the potential of the terminal T₂. By turning on the switch S₃ and the switch S₄ and turning off the switch S₁ and the switch S₂, the potential of the terminal T₄ becomes 0 V, which is substantially the same as the potential of the terminal T₃. That is, by periodically turning on and off the switches S₁ to S₄, the constant voltage applied between the terminal T₁ and the terminal T₂ and between the terminal T₂ and the terminal T₃ can be output as an AC voltage from the terminal T₄.

The switches S₁ to S₄ and the diodes D₁ to D₆ may be vertical semiconductor chips.

The material for the diodes D₁ to D₆ may be silicon. In addition, the material is not limited to silicon, but may be a wide band gap semiconductor. For example, the material may be SiC, GaN, diamond, AlN or ZnO. Additionally, although the diodes D₁ to D₆ may have similar performance, in order to minimize circuit loss, it is preferable that the forward voltages of the diode D₅ and the diode D₆ be smaller than those of the diodes D₁ to D₄, and that the reverse recovery loss of the diodes D₁ to D₄ be smaller than those of the diode D₅ and the diode D₆.

The reason is described. The reverse recovery loss of the diodes D₁ to D₄ increases the turn-on loss of the switches S₁ to S₄, and the conduction time depends on the on/off period of the switches S₁ to S₄. Therefore, the reverse recovery loss has a greater influence on the total loss of the inverter than the conduction loss caused by the forward voltage. On the other hand, the diodes D₅ and D₆ do not affect the on/off period of the switches S₁ to S₄, and therefore the conduction loss caused by the forward voltage has a greater influence on the total loss of the inverter than the reverse recovery loss.

The material for the switches S₁ to S₄ may be silicon. In addition, the material is not limited to silicon, but may be a wide band gap semiconductor. Additionally, each of the switches S₁ to S₄ may be an IGBT or a MOSFET (Metal Oxide Semiconductor Field Effect Transistor).

Each of the combinations of a switch and a diode, i.e., the switch S₁ and the diode D₁, the switch S₂ and the diode D₂, the switch S₃ and the diode D₃, and the switch S₄ and the diode D₄, may be an integrated semiconductor chip, and may be, for example, an RC (Reverse Conducting)-IGBT or a MOSFET.

### Embodiment 1

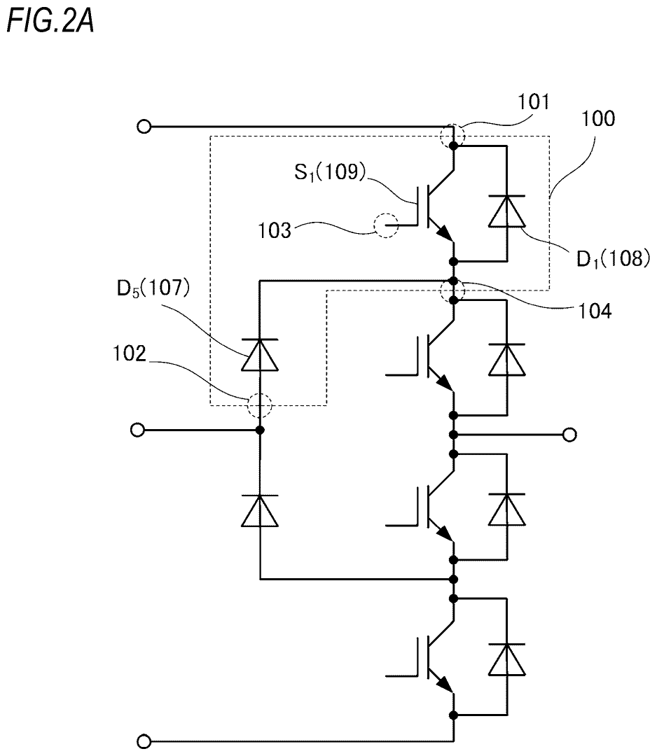

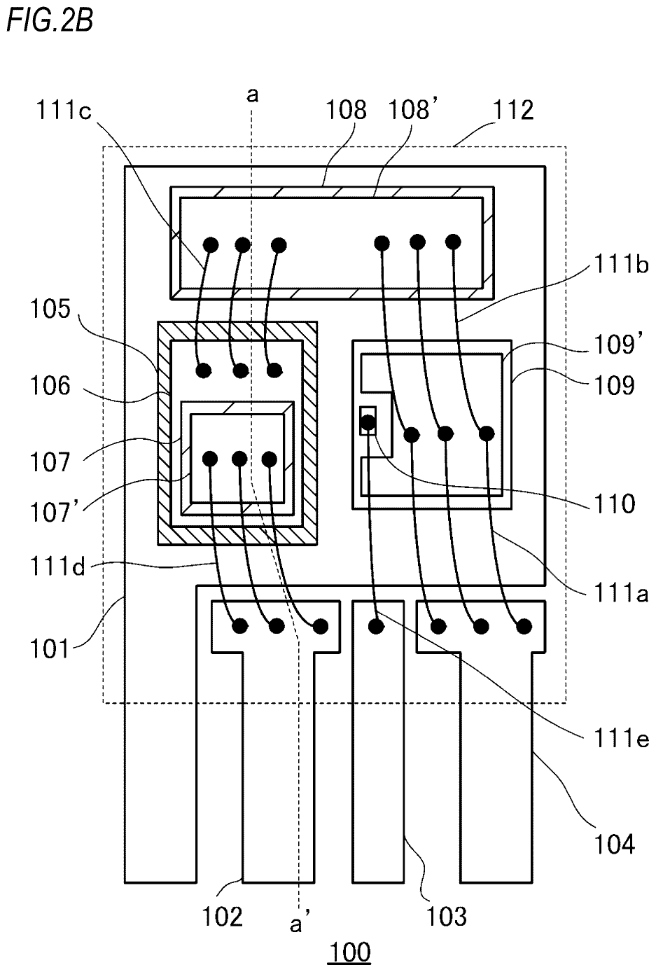

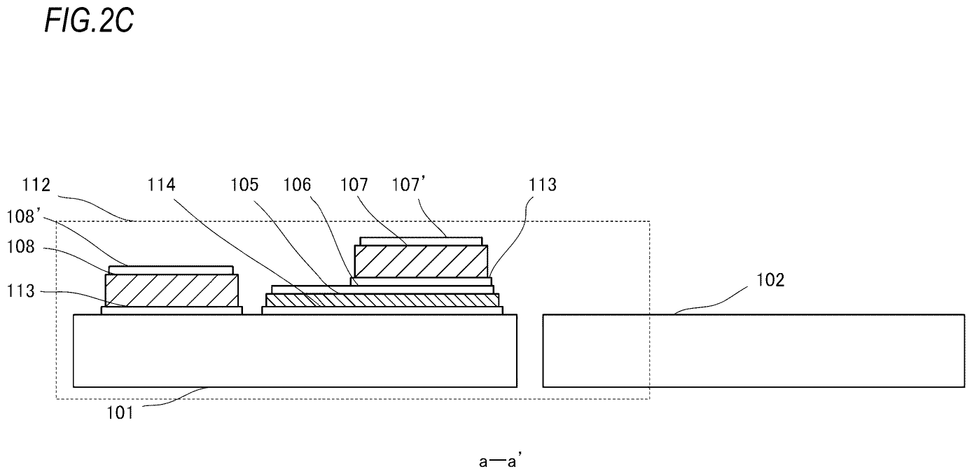

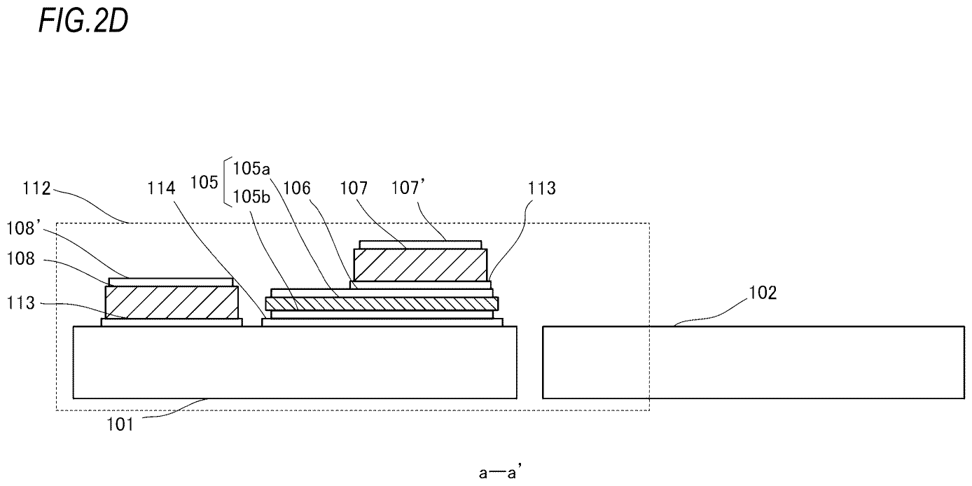

FIG. 2A, FIG. 2B, FIG. 2C, and FIG. 2D illustrate a configuration of a semiconductor module 100 according to Embodiment 1, in which FIG. 2A is a circuit diagram of the semiconductor module 100, FIG. 2B is a plan view, and FIG. 2C and FIG. 2D are cross-sectional views of the semiconductor module 100 taken along line a-a′ shown in FIG. 2B. In FIGS. 2B, 2C and 2D, only the outline of a resin 112 is indicated by a broken line for convenience of illustration.

As illustrated in FIG. 2A, the semiconductor module 100 includes the switch S₁, the diode D₁, and the diode D₅ in FIG. 1. As illustrated in FIG. 2B, the semiconductor module 100 includes an insulating substrate 105, a diode 108, and a switch 109 on a lead frame 101. The insulating substrate 105 has a wiring layer 106 on one surface. Additionally, a diode 107 is provided on the wiring layer 106. The diode 107 has an anode pad 107′ provided on a surface opposite to a surface facing the lead frame 101. In addition, similarly, the diode 108 and the switch 109 have an anode pad 108′ and an emitter pad 109′, respectively, which are provided on surfaces opposite to surfaces facing the lead frame 101. In addition, the present embodiment includes a wiring 111a connecting a first lead 104 and the emitter pad 109′ to each other, a wiring 111b connecting the emitter pad 109′ and the anode pad 108′ to each other, a wiring 111c connecting the anode pad 108′ and the wiring layer 106 to each other, and a wiring 111d connecting the anode pad 107′ and a second lead 102 to each other. Additionally, a gate pad 110 is mounted on the switch 109. A wiring 111e connecting the gate pad 110 and a third lead 103 to each other is provided. Note that, in Embodiment 1, the switch S₁, the diode D₁, and the diode D₅ correspond to the switch 109, the diode 108, and the diode 107, respectively.

The lead frame 101, the first lead 104, the second lead 102, and the third lead 103 are provided spaced apart from each other, and have extended portions, and the extended portions are parallel to each other. In addition, in the extended portions of the first lead 104, the second lead 102, and the third lead 103, sides perpendicular to the extension direction face one side of the lead frame. The leads and the lead frame have the same positional relationship in other embodiments as well.

The diode 107, the diode 108, the switch 109, the insulating substrate 105, and the wirings 111a to 111e on the lead frame 101 are covered by the resin 112, but portions of the lead frame 101 and the leads 102 to 104 protrude from the resin 112 along the same direction.

The lead frame 101, the first lead 104, the second lead 102, the third lead 103, the wiring layer 106, the anode pad 107′, the anode pad 108′, the emitter pad 109′, and the gate pad 110 are made of a conductive material, such as aluminum, iron, cobalt, nickel, copper or an alloy thereof.

The wirings 111a to 111e may be formed by wire bonding, or may be made of plate-shaped metal. The number of wirings 111a to 111e is not limited to that illustrated in the drawing, and may be changed as appropriate. In addition, the wirings 111a to 111e are made of a conductive material, such as aluminum, copper, gold, or an alloy thereof.

The insulating substrate 105 may be made of an insulator such as ceramic or resin. In addition, in the insulating substrate 105, a conductive layer similar to the wiring layer 106 may be provided on a surface opposite to a surface on which the wiring layer 106 is provided.

The diode 107 and the diode 108 may have similar performance; however, in order to minimize circuit loss, it is preferable that the forward voltage of the diode 107 be smaller than that of the diode 108, and that the reverse recovery loss of the diode 108 be smaller than that of the diode 107.

As illustrated in FIG. 2C, the lead frame 101 and the diode 108, and the wiring layer 106 and the diode 107 are joined (bonded) to each other via respective joining members 113.

Although not specifically illustrated here, the lead frame 101 and the switch 109 are also similarly joined to each other via a joining member 113.

The joining member 113 may be made of, for example, lead, tin, silver or an alloy thereof.

Additionally, the lead frame 101 and the insulating substrate 105 are joined to each other via a joining member 114.

The joining member 114 may be made of an insulating material such as epoxy resin or silicone resin, preferably a material having high thermal conductivity. By selecting a material having high thermal conductivity, heat generated by the diode 107 can be efficiently dissipated to the lead frame 101.

The configuration of FIG. 2D is different from that illustrated in FIG. 2C, in that the insulating substrate 105 includes an insulating layer 105a and a conductive layer 105b, and the conductive layer 105b is provided between the insulating layer 105a and the joining member 114. The conductive layer 105a may be made of, for example, aluminum, iron, cobalt, nickel, copper or an alloy thereof, as in the wiring layer 106. By providing the conductive layer 105a, heat generated by the diode 107 can be easily transferred to the lead frame 101.

In this case, the joining member 114 may be made of an insulating material such as epoxy resin or silicone resin, or lead, tin, silver or an alloy thereof, preferably a material having high thermal conductivity. By selecting a material having high thermal conductivity, heat generated by the diode 107 can be efficiently dissipated to the lead frame 101.

By the above configuration, a semiconductor module including the switch S₁, the diode D₁, and the diode D₅ can be accommodated within a TO package.

Note that, although the illustration and description are omitted for convenience of explanation, in other embodiments as well, the semiconductor chip, the insulating substrate, the wiring, and portions of the lead frame and the lead that constitute the semiconductor module are covered by the resin 112.

In other embodiments as well, the lead frame and the switch, and the lead frame and the diode are similarly joined to each other by a conductive material. Additionally, the lead frame and the insulating substrate are similarly joined to each other by a conductive material or an insulating material.

### Embodiment 2

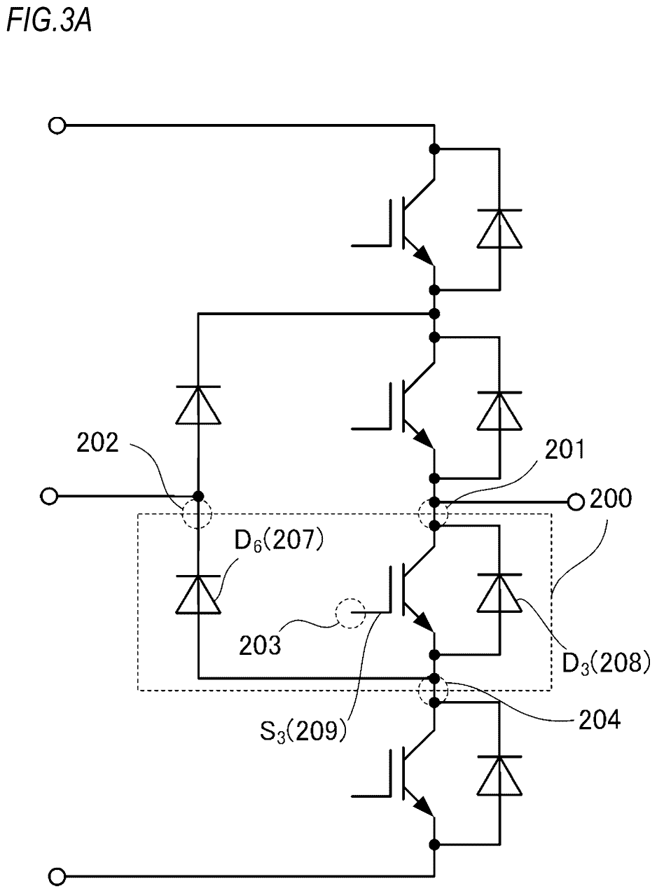

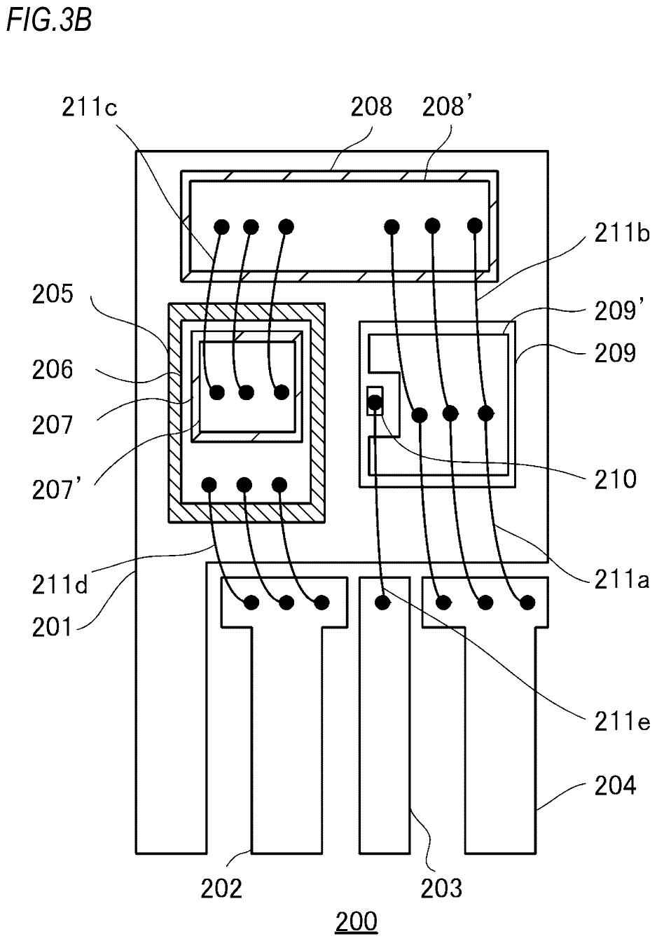

FIG. 3A and FIG. 3B illustrate a configuration of a semiconductor module 200 according to Embodiment 2, in which FIG. 3A is a circuit diagram of the semiconductor module 200, and FIG. 3B is a plan view. As illustrated in FIG. 3A, the semiconductor module 200 includes the switch S₃, the diode D₃, and the diode D₆ in FIG. 1. As illustrated in FIG. 3B, the semiconductor module 200 includes an insulating substrate 205, a diode 208, and a switch 209 on a lead frame 201. The insulating substrate 205 has a wiring layer 206 on one surface. Additionally, a diode 207 is provided on the wiring layer 206. The diode 207 has an anode pad 207′ provided on a surface opposite to a surface facing the lead frame 201. Similarly, the diode 208 and the switch 209 also have an anode pad 208′ and an emitter pad 209′, respectively, which are provided on surfaces opposite to surfaces facing the lead frame 201. The present embodiment includes a wiring 211a connecting a first lead 204 and the emitter pad 209′ to each other, a wiring 211b connecting the emitter pad 209′ and the anode pad 208′ to each other, a wiring 211c connecting the anode pad 208′ and the anode pad 207′ to each other, and a wiring 211d connecting the wiring layer 206 and a second lead 202 to each other. A gate pad 210 is mounted on the switch 209. A wiring 211e connecting the gate pad 210 and a third lead 203 to each other is provided. Note that, in Embodiment 2, the switch S₃, the diode D₃, and the diode D₆ correspond to the switch 209, the diode 208, and the diode 207, respectively.

The diode 207 and the diode 208 may have similar performance; however, in order to minimize circuit loss, it is preferable that the forward voltage of the diode 207 be smaller than that of the diode 208, and that the reverse recovery loss of the diode 208 be smaller than that of the diode 207.

By the above configuration, a semiconductor module including the switch S₃, the diode D₃, and the diode D₆ can be accommodated within a TO package.

### Embodiment 3

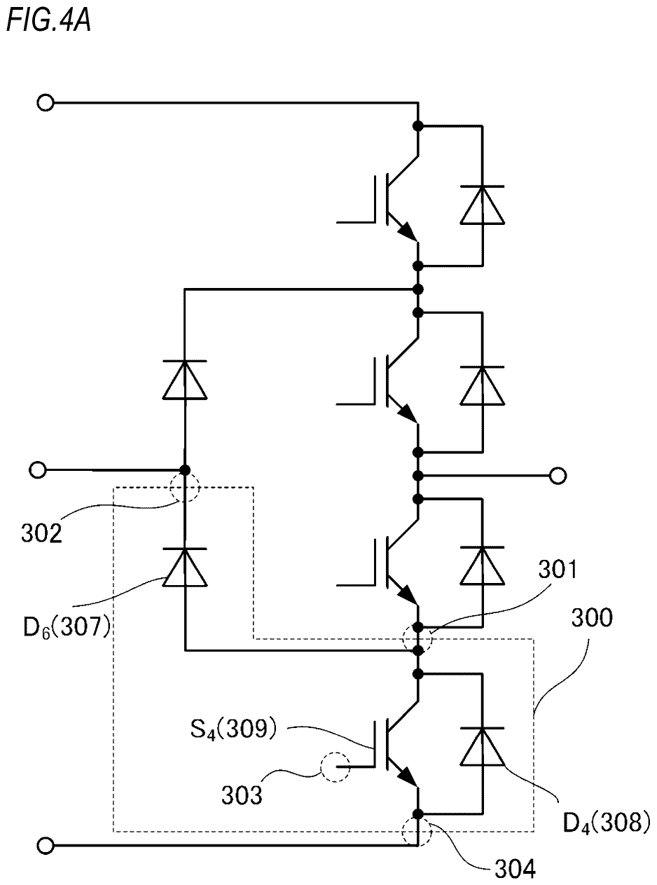

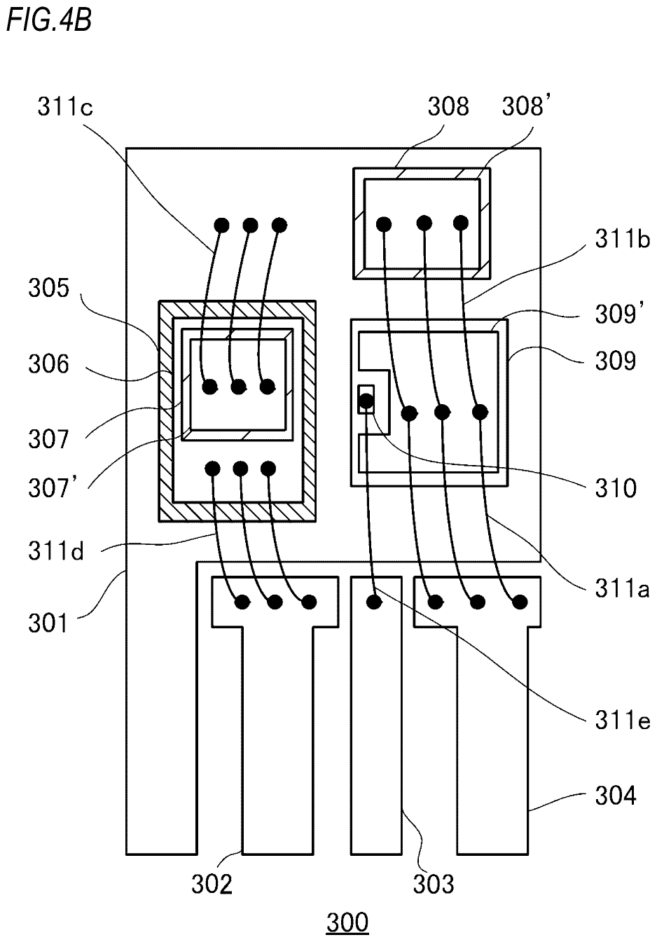

FIG. 4A and FIG. 4B illustrate a configuration of a semiconductor module 300 according to Embodiment 3, in which FIG. 4A is a circuit diagram of the semiconductor module 300, and FIG. 4B is a plan view. As illustrated in FIG. 4A, the semiconductor module 300 includes the switch S₄, the diode D₄, and the diode D₆ in FIG. 1. As illustrated in FIG. 4B, the semiconductor module 300 includes an insulating substrate 305, a diode 308, and a switch 309 on a lead frame 301. The insulating substrate 305 has a wiring layer 306 on one surface. Additionally, a diode 307 is provided on the wiring layer 306. The diode 307 has an anode pad 307′ provided on a surface opposite to a surface facing the lead frame 301. In addition, similarly, the diode 308 and the switch 309 also have an anode pad 308′ and an emitter pad 309′, respectively, which are provided on surfaces opposite to surfaces facing the lead frame 301. The present embodiment includes a wiring 311a connecting a first lead 304 and the emitter pad 309′ to each other, a wiring 311b connecting the emitter pad 309′ and the anode pad 308′ to each other, a wiring 311c connecting the lead frame 301 and the anode pad 307′ to each other, and a wiring 311d connecting the wiring layer 306 and a second lead 302 to each other. A gate pad 310 is mounted on the switch 309. A wiring 311e connecting the gate pad 310 and a third lead 303 to each other is provided. Note that, in Embodiment 3, the switch S₄, the diode D₄, and the diode D₆ correspond to the switch 309, the diode 308, and the diode 307, respectively.

The diode 307 and the diode 308 may have similar performance; however, in order to minimize circuit loss, it is preferable that the forward voltage of the diode 307 be smaller than that of the diode 308, and that the reverse recovery loss of the diode 308 be smaller than that of the diode 307.

By the above configuration, a semiconductor module including the switch S₄, the diode D₄, and the diode D₆ can be accommodated within a TO package.

The present invention is not limited to the configurations of the above embodiments, and can be appropriately changed. For example, as described above, the switch 109, the switch 209, and the switch 309 may be RC-IGBTs or MOSFETs. Additionally, the position of the gate pad on the switch can be changed and, accordingly, the position of the lead can be changed.

### Modification 1-1

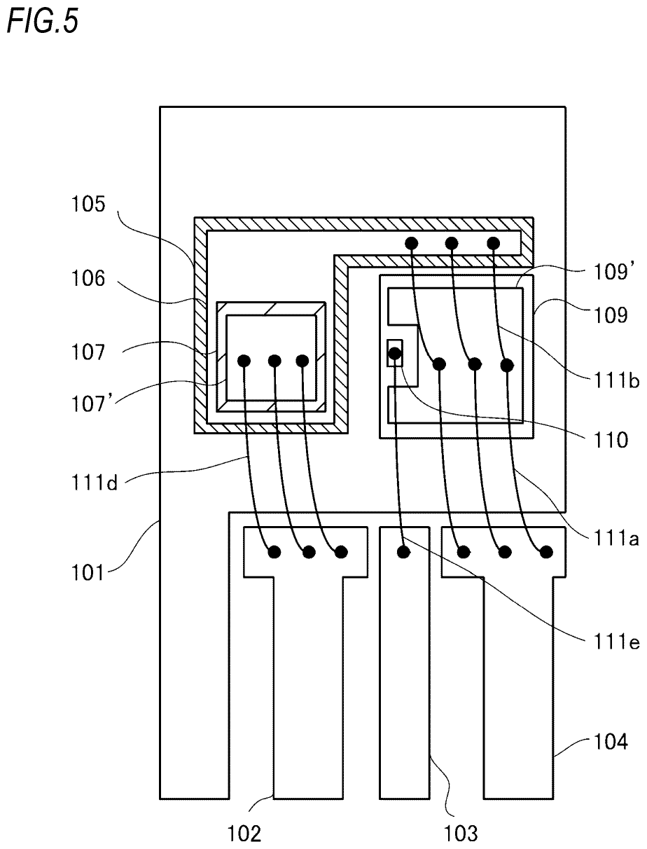

FIG. 5 illustrates Modification 1-1 of Embodiment 1. An insulating substrate 105 and a switch 109 are provided on a lead frame 101. The insulating substrate 105 has a wiring layer 106 on one surface. Additionally, a diode 107 is provided on the wiring layer 106. The diode 107 has an anode pad 107′ provided on a surface opposite to a surface facing the lead frame 101. In addition, similarly, the diode 109 also has an emitter pad 109′ provided on a surface opposite to a surface facing the lead frame 101. The present modification includes a wiring 111a connecting a first lead 104 and the emitter pad 109′ to each other, a wiring 111b connecting the emitter pad 109′ and the wiring layer 106 to each other, and a wiring 111d connecting the anode pad 107′ and a second lead 102 to each other. A gate pad 110 is mounted on the switch 109. A wiring 111e connecting the gate pad 110 and a third lead 103 to each other is provided.

In Modification 1-1, the switch 109 is limited to an RC-IGBT or a MOSFET.

By having the switch 109 also perform the function of the diode 108 in Embodiment 1, the number of semiconductor chips in the semiconductor module can be reduced, and the semiconductor module can be accommodated within a TO package smaller than in Embodiment 1.

### Modification 1-2

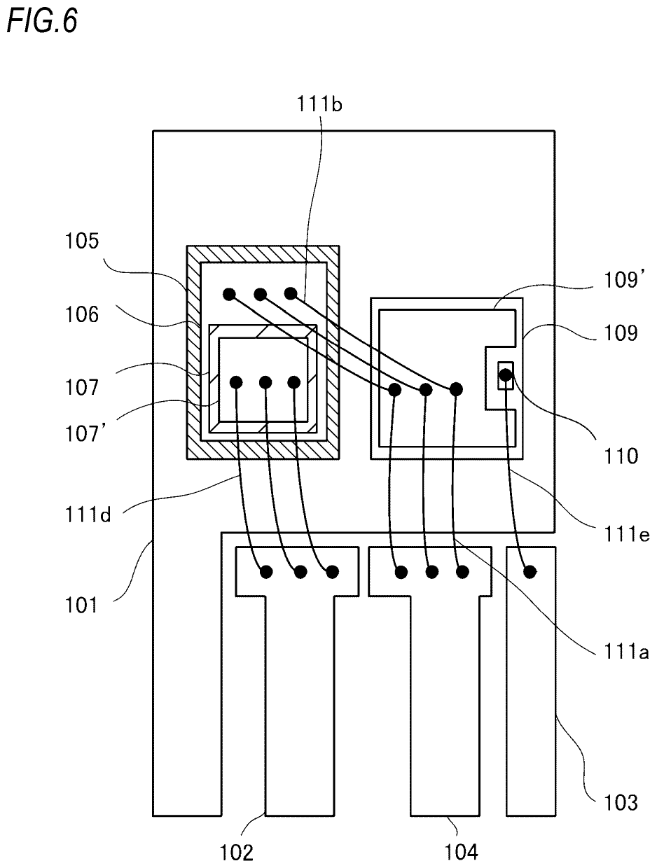

FIG. 6 illustrates Modification 1-2 of Embodiment 1. Modification 1-2 is different from Modification 1-1 in that the first lead 104 is arranged between the second lead 102 and the third lead 103, and that the gate pad 110 mounted on the switch 109 is arranged in an opposite direction to that of the diode 107. With this configuration, even when the wiring 111b is extended from the emitter pad 109′ in any direction of the wiring layer 106, it is possible to prevent the wiring 111b from approaching the wiring 111e. Accordingly, an improvement in reliability can be expected. In addition, compared with Modification 1-1, the insulating substrate 105 can be formed into a simpler shape, making the manufacturing process easier.

In Modification 1-2, the switch 109 is limited to an RC-IGBT or a MOSFET.

### Modification 2-1

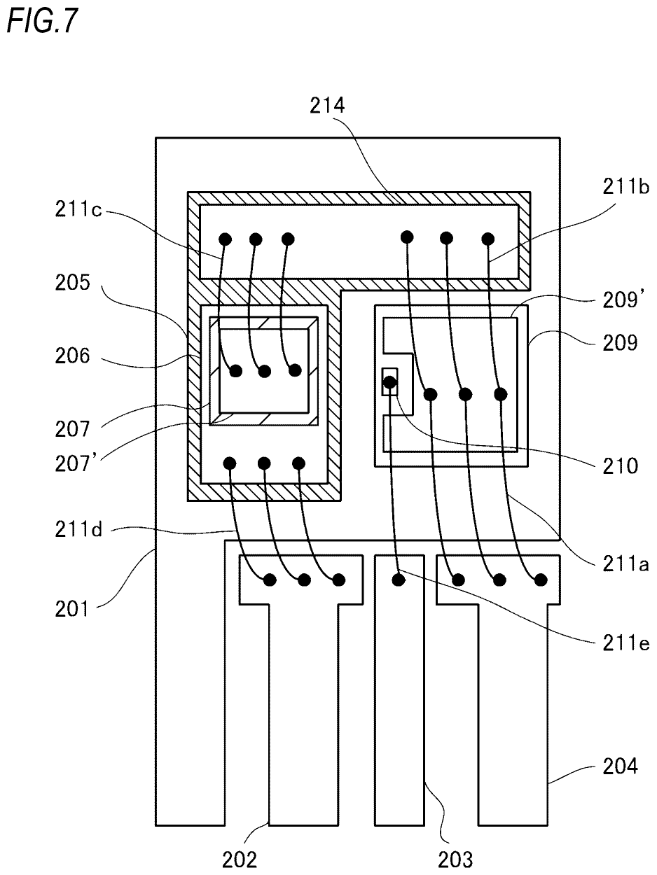

FIG. 7 illustrates Modification 2-1 of Embodiment 2. An insulating substrate 205 and a switch 209 are provided on a lead frame 201. In addition, a wiring layer 206 and a wiring layer 214 are provided on the insulating substrate 205, spaced apart from each other, and a diode 207 is arranged on the wiring layers 206. The diode 207 has an anode pad 207′ provided on a surface opposite to a surface facing the lead frame 201. In addition, similarly, the switch 209 also has an emitter pad 209′ provided on a surface opposite to a surface facing the lead frame 201. The present modification includes a wiring 211a connecting a first lead 204 and the emitter pad 209′ to each other, a wiring 211b connecting the emitter pad 209′ and the wiring layer 214 to each other, a wiring 211c connecting the wiring layer 214 and the anode pad 207′ to each other, and a wiring 211d connecting the wiring layer 206 and a second lead 202 to each other. A gate pad 210 is mounted on the switch 209. A wiring 211e connecting the gate pad 210 and a third lead 203 to each other is provided.

In Modification 2-1, the switch 209 is limited to an RC-IGBT or a MOSFET.

### Modification 2-2

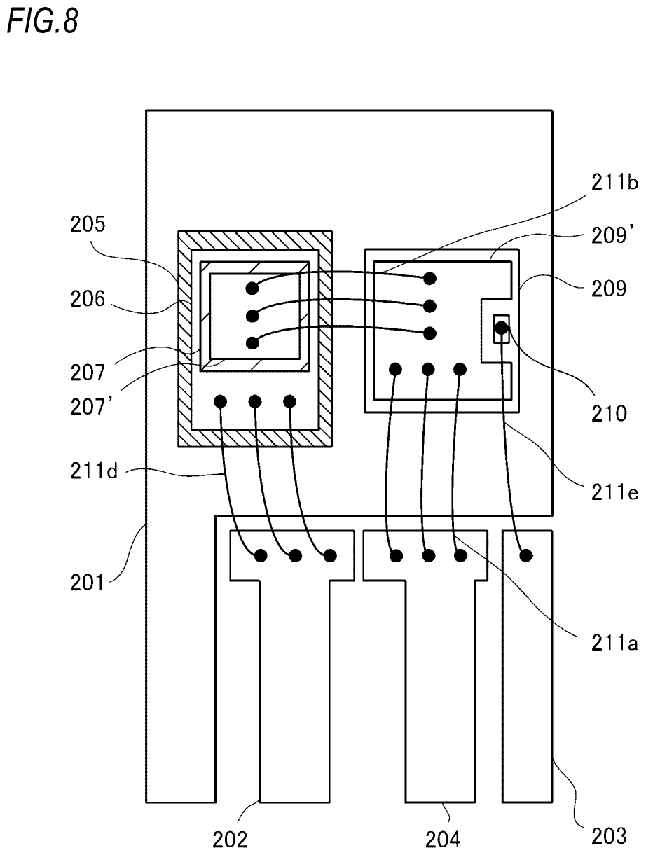

FIG. 8 illustrates Modification 2-2 of Embodiment 2. An insulating substrate 205 and a switch 209 are provided on a lead frame 201. The insulating substrate 205 has a wiring layer 206 on one surface. Additionally, a diode 207 is arranged on the wiring layer 206. The diode 207 has an anode pad 207′ provided on a surface opposite to a surface facing the lead frame 201. In addition, similarly, the switch 209 also has an emitter pad 209′ provided on a surface opposite to a surface facing the lead frame 201. The present modification includes a wiring 211a connecting a first lead 204 and the emitter pad 209′ to each other, a wiring 211b connecting the emitter pad 209′ and the anode pad 207′ to each other, and a wiring 211d connecting the wiring layer 206 and a second lead 202 to each other. The first lead 204 is arranged between the second lead 202 and the third lead 203, and the gate pad 210 mounted on the switch 209 is arranged in an opposite direction to that of the diode 207.

By arranging the gate pad 210 mounted on the switch 209 in the opposite direction to that of the diode 207, it is possible to prevent the wiring 211b approaching the wiring 211e. Accordingly, an improvement in reliability can be expected. Additionally, the emitter pad 209′ and the anode pad 207′ can be directly connected to each other by the wiring 211b. Accordingly, there is no need to provide the wiring layer 214 of Modification 2-1, and the semiconductor module can be accommodated within a TO package smaller than in Embodiment 2 and Modification 2-1. In addition, since the number of components can be reduced, the manufacturing cost can be reduced.

In Modification 2-2, the switch 209 is limited to an RC-IGBT or a MOSFET.

### Modification 3

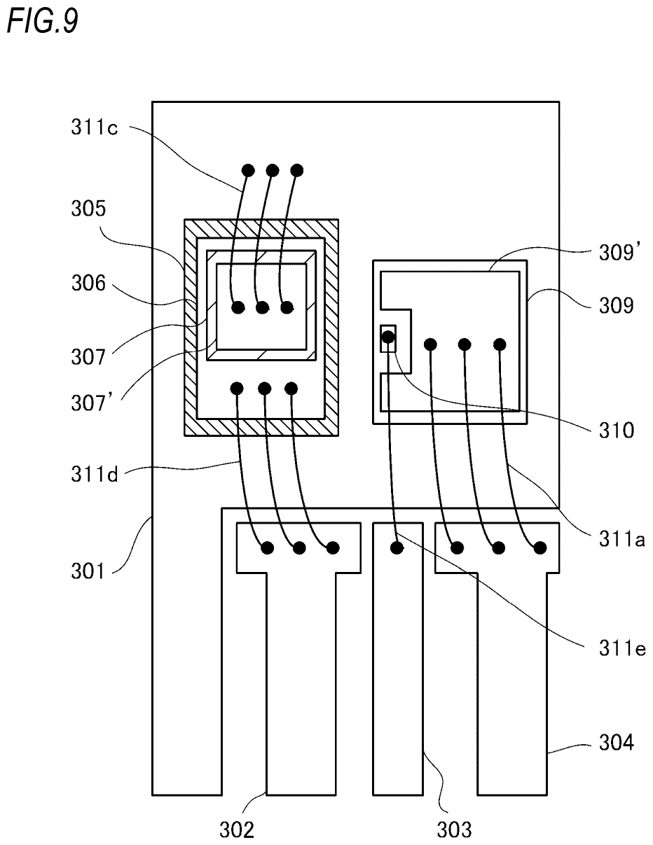

FIG. 9 illustrates Modification 3 of Embodiment 3. An insulating substrate 305 and a switch 309 are provided on a lead frame 301. The insulating substrate 305 has a wiring layer 306 on one surface. Additionally, a diode 307 is provided on the wiring layer 306. The diode 307 has an anode pad 307′ provided on a surface opposite to a surface facing the lead frame 301. In addition, similarly, the switch 309 also has an emitter pad 309′ provided on a surface opposite to a surface facing the lead frame 301. The present modification includes a wiring 311a connecting a first lead 304 and the emitter pad 309′ to each other, a wiring 311c connecting the lead frame 301 and the anode pad 307′ to each other, and a wiring 311d connecting the wiring layer 306 and a second lead 302 to each other. A gate pad 310 is mounted on the switch 309. A wiring 311e connecting the gate pad 310 and a third lead 303 to each other is provided.

In Modification 3, the switch 309 is limited to an RC-IGBT or a MOSFET.

By having the switch 309 also perform the function of the diode 308 in Embodiment 1, the number of semiconductor chips in the semiconductor module can be reduced, and the semiconductor module can be accommodated within a TO package smaller than in Embodiment 1.

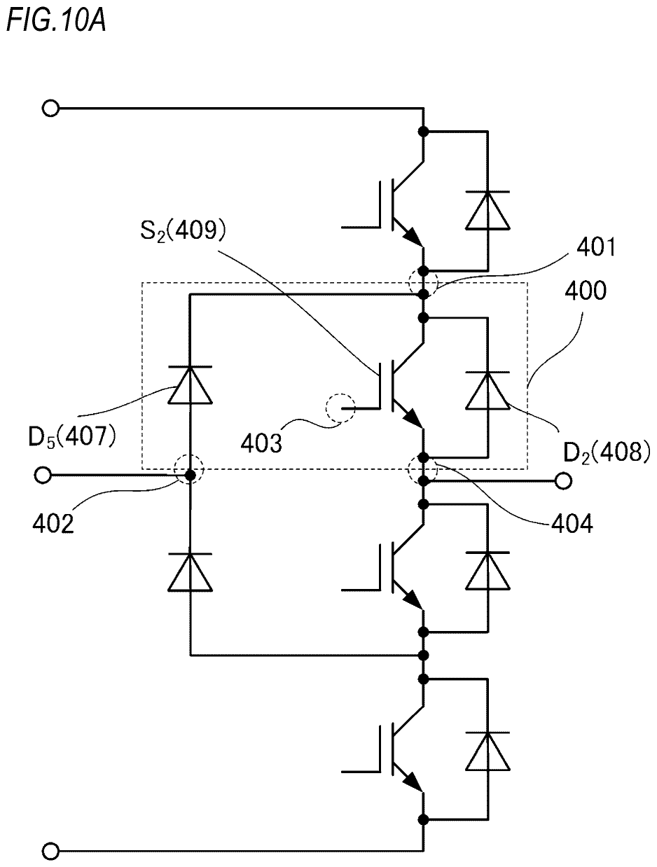

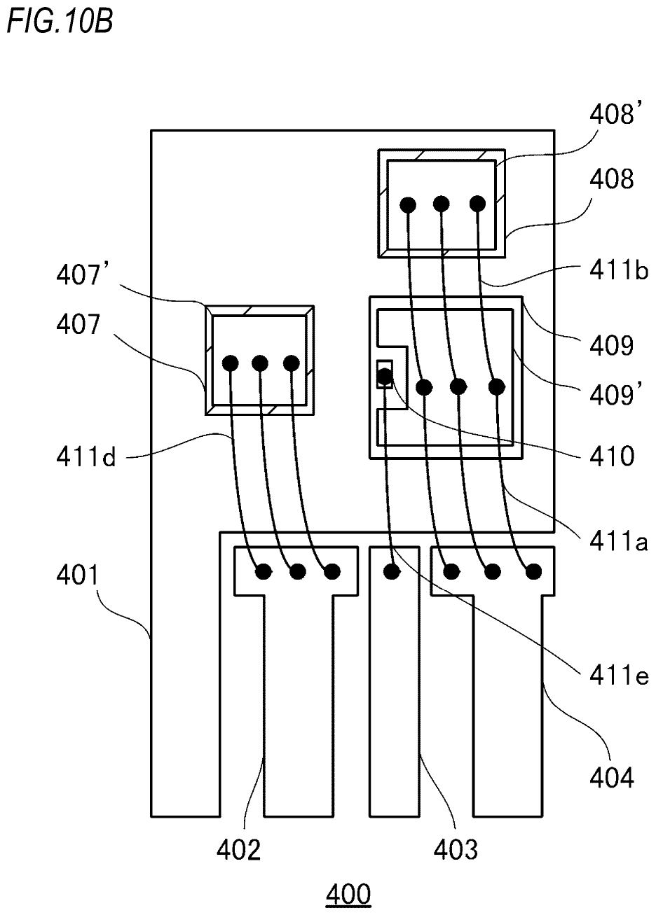

FIG. 10A and FIG. 10B illustrate a configuration of a semiconductor module 400 that can be incorporated into the power conversion device 1 illustrated in FIG. 1, in which FIG. 10A is a circuit diagram of the semiconductor module 400, and FIG. 10B is a plan view. As illustrated in FIG. 10A, the semiconductor module 400 includes the switch S₂, the diode D₂, and the diode D₅ in FIG. 1. As illustrated in FIG. 10B, the semiconductor module 400 includes a diode 407, a diode 408, and a switch 409 on a lead frame 401, and the diode 407 has an anode pad 407′ on a surface opposite to a surface facing the lead frame 401. In addition, similarly, the diode 408 and the switch 409 also have an anode pad 408′ and an emitter pad 409′, respectively, which are provided on surfaces opposite to surfaces facing the lead frame 401. A wiring 411a connecting a first lead 404 and the emitter pad 409′ to each other, a wiring 411b connecting the emitter pad 409′ and the anode pad 408′ to each other, and a wiring 411d connecting the anode pad 407′ and a second lead 402 to each other are provided. A gate pad 410 is mounted on the switch 409. A wiring 411e connecting the gate pad 410 and a third lead 403 to each other is provided. Here, the switch S₂, the diode D₂, and the diode D₅ correspond to the switch 409, the diode 408, and the diode 407, respectively.

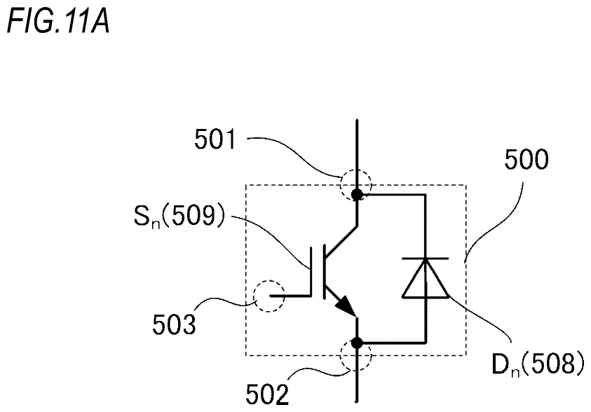

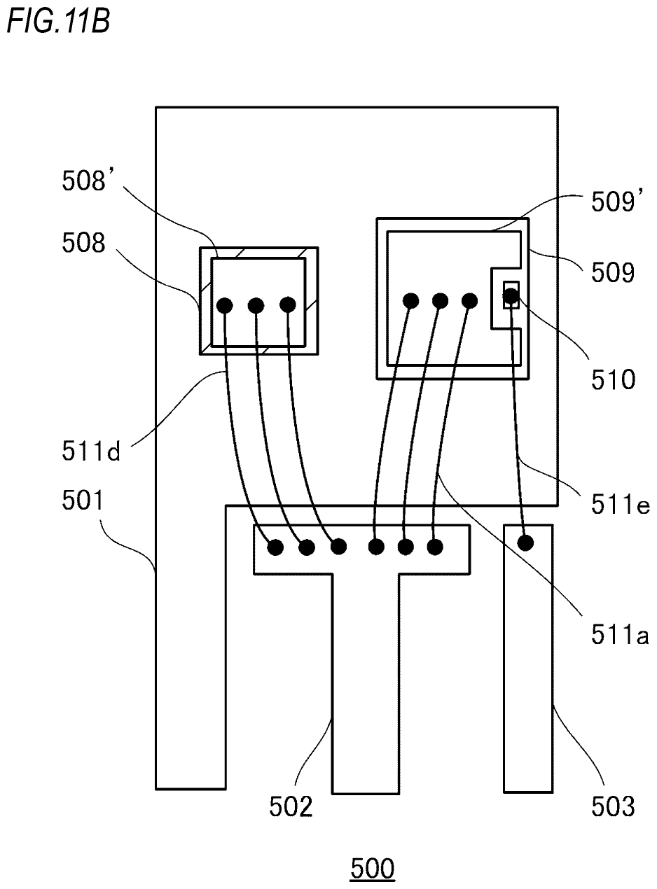

FIG. 11A and FIG. 11B illustrate a configuration of a semiconductor module 500 that can be incorporated into the power conversion device 1 illustrated in FIG. 1, in which FIG. 11A is a circuit diagram of the semiconductor module 500, and FIG. 11B is a plan view. As illustrated in FIG. 11A, the semiconductor module 500 includes the switch Sn (n is any natural number equal to or less than 4), and the diode Dₙ in FIG. 1. As illustrated in FIG. 11B, the semiconductor module 500 includes a diode 508 and a switch 509 on a lead frame 501, and the diode 508 has an anode pad 508′ on a surface opposite to a surface facing the lead frame 501. In addition, similarly, the switch 509 also has an emitter pad 509′ provided in an opposite direction to that of the lead frame 501. A wiring 511a connecting the second lead 502 and the emitter pad 509′ to each other, and a wiring 511d connecting the anode pad 508′ and the second lead 502 to each other are provided. A gate pad 510 is mounted on the switch 509. A wiring 511e connecting the gate pad 510 and a third lead 503 to each other is provided. Here, the switch Sₙ and the diode Dₙ correspond to the switch 509 and the diode 508, respectively.

### Combination 1

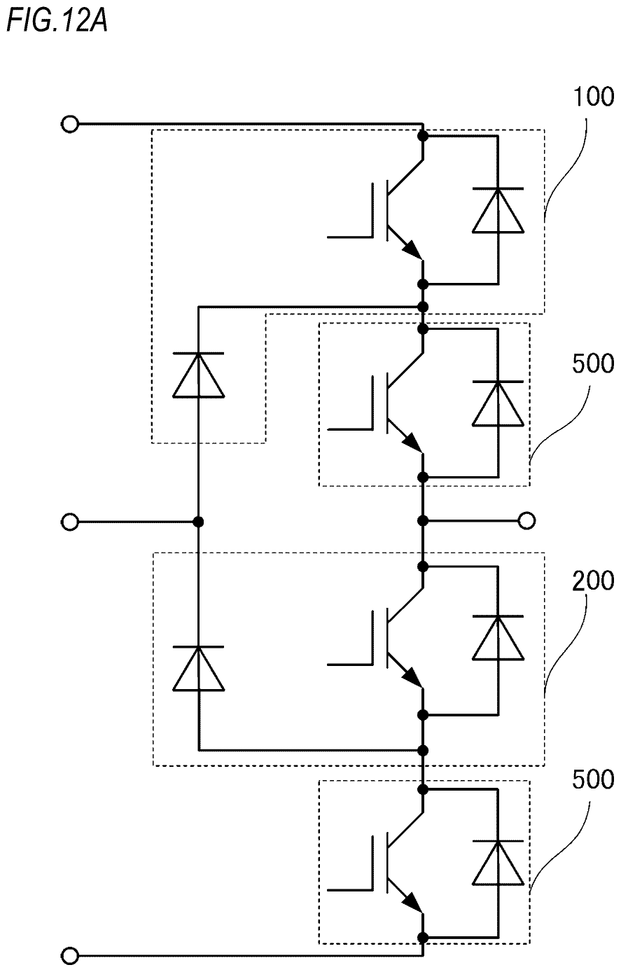

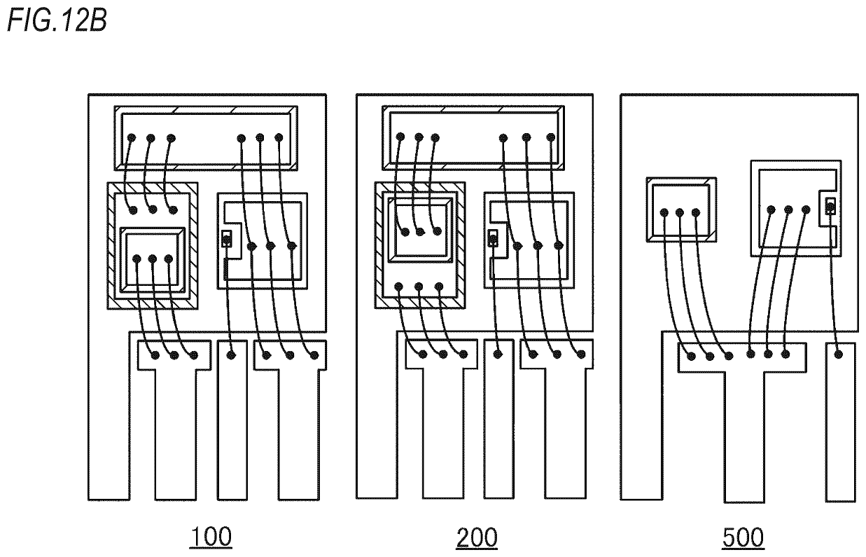

FIG. 12A and FIG. 12B illustrate combination 1 of semiconductor modules in manufacturing the power conversion device 1 illustrated in FIG. 1, in which FIG. 12A is a circuit diagram, and FIG. 12B is a schematic diagram of semiconductor modules constituting the circuit. The power conversion device 1 can be manufactured by mounting one semiconductor module 100, one semiconductor module 200, and two semiconductor modules 500 on a printed circuit board or the like.

### Combination 2

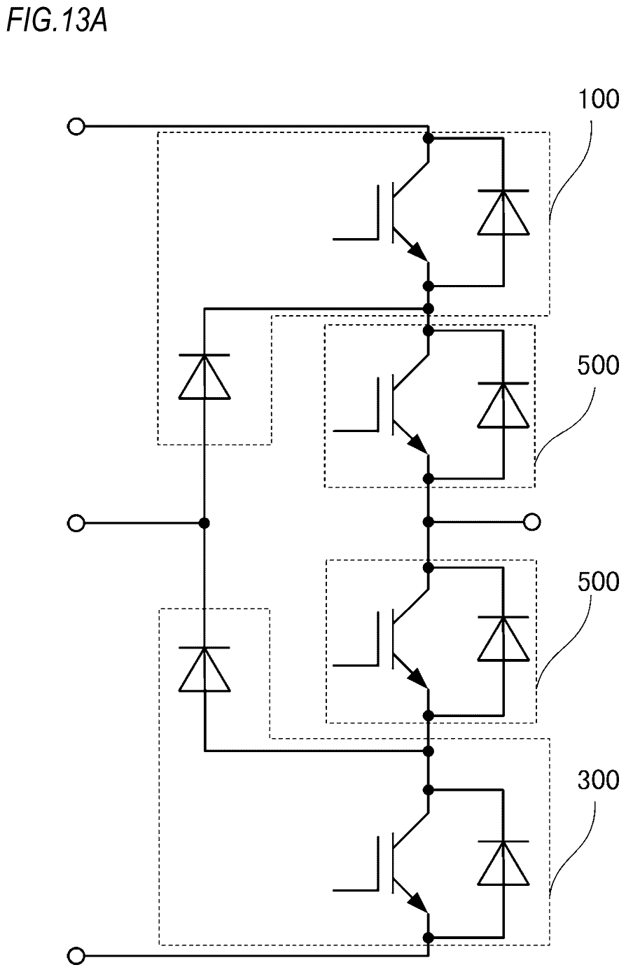

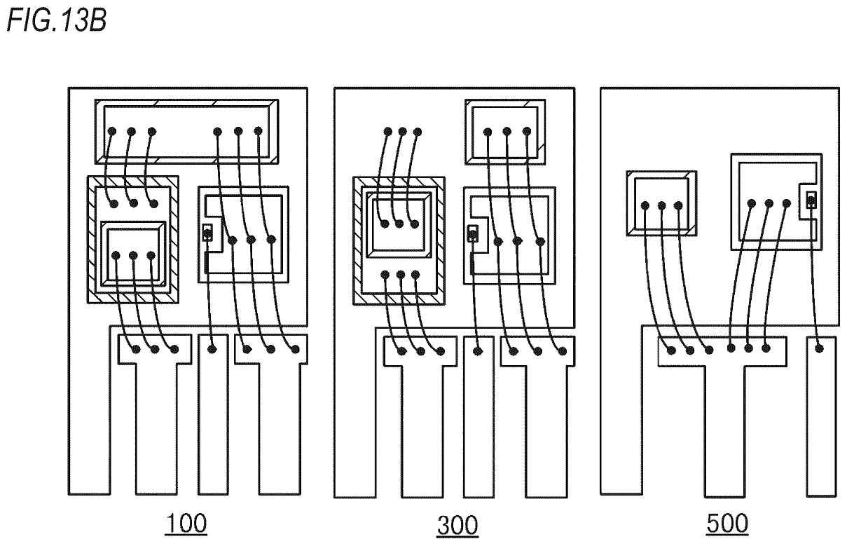

FIG. 13A and FIG. 13B illustrate combination 2 of semiconductor modules in manufacturing the power conversion device 1 illustrated in FIG. 1, in which FIG. 13A is a circuit diagram, and FIG. 13B is a schematic diagram of semiconductor modules constituting the circuit. The power conversion device 1 can be manufactured by mounting one semiconductor module 100, one semiconductor module 300, and two semiconductor modules 500 on a printed circuit board or the like.

### Combination 3

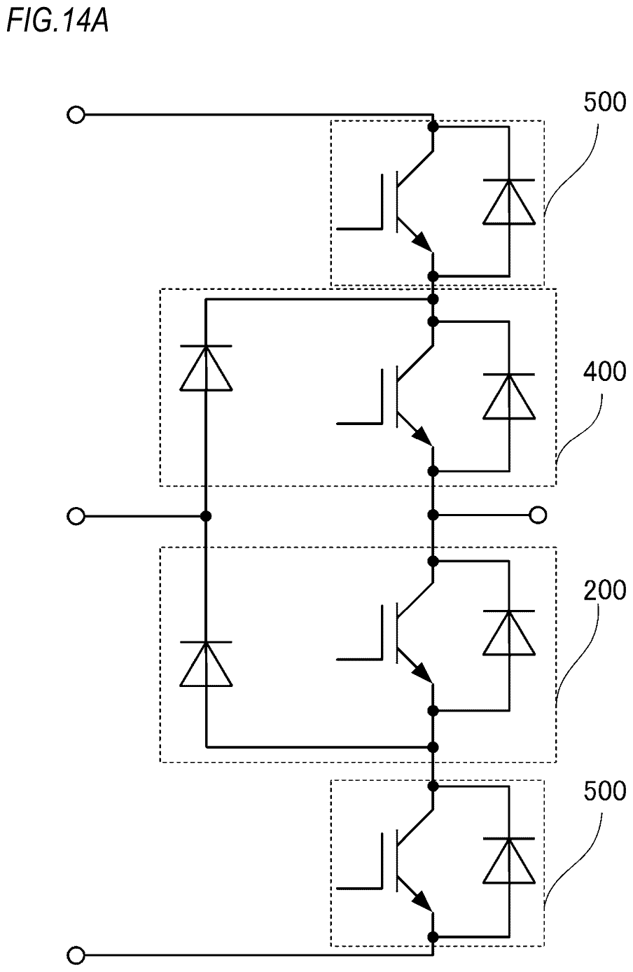

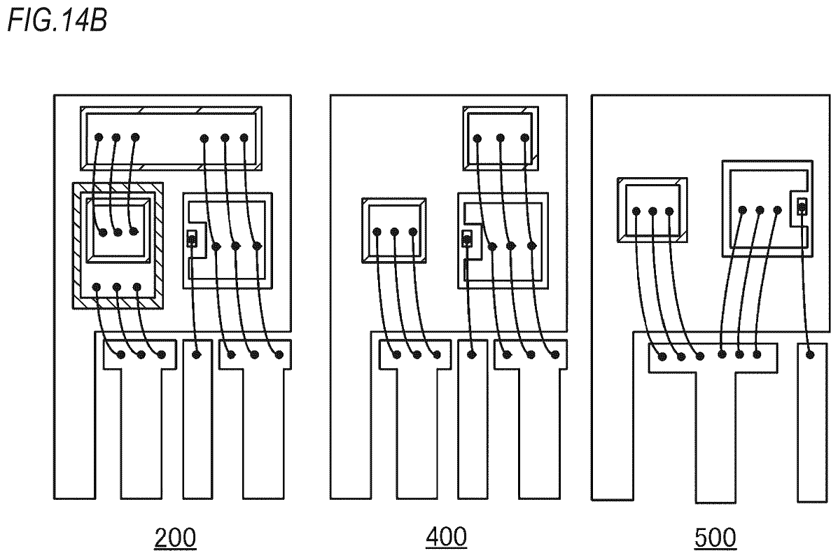

FIG. 14A and FIG. 14B illustrate combination 3 of semiconductor modules in manufacturing the power conversion device 1 illustrated in FIG. 1, in which FIG. 14A is a circuit diagram, and FIG. 14B is a schematic diagram of semiconductor modules constituting the circuit. The power conversion device 1 can be manufactured by mounting one semiconductor module 400, one semiconductor module 200, and two semiconductor modules 500 on a printed circuit board or the like.

### Combination 4

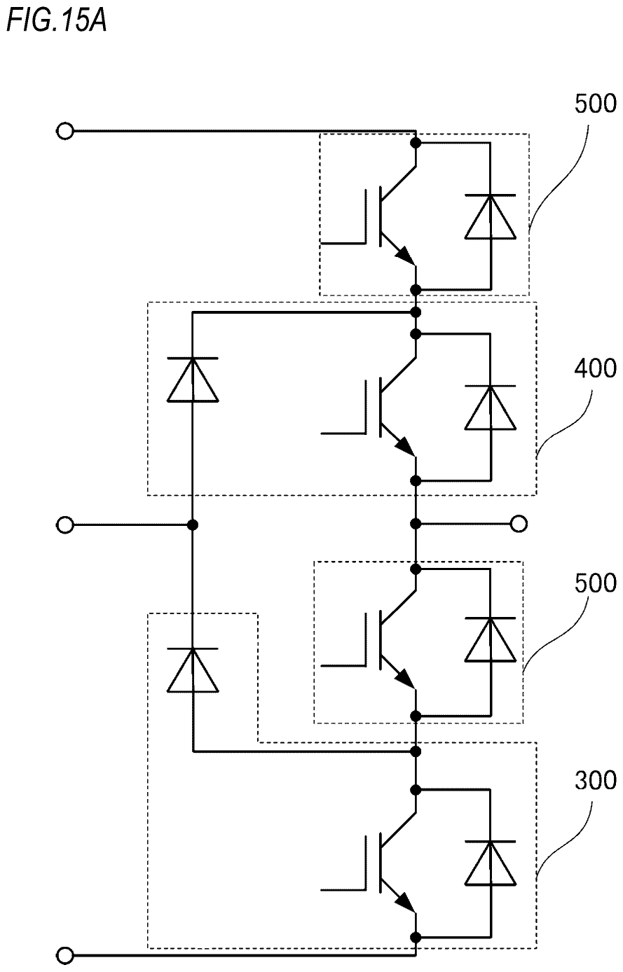

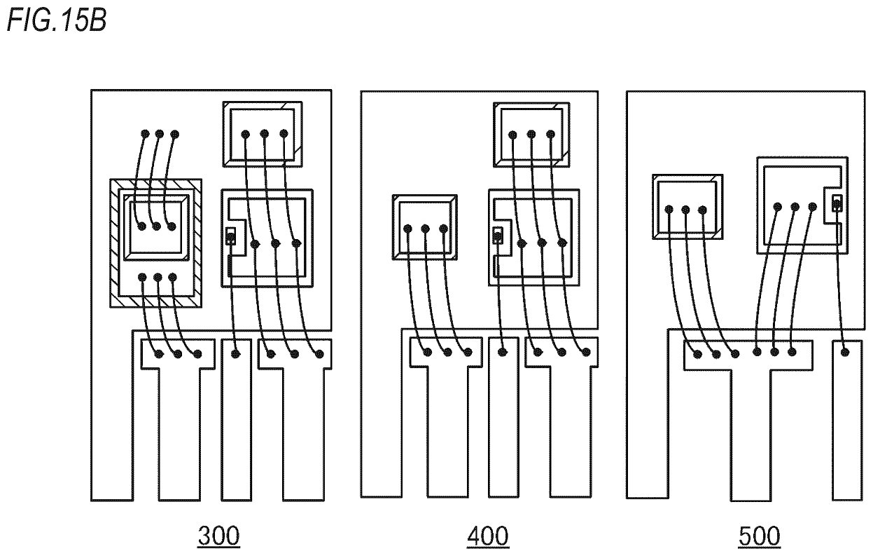

FIG. 15A and FIG. 15B illustrate combination 4 of semiconductor modules in manufacturing the power conversion device 1 illustrated in FIG. 1, in which FIG. 15A is a circuit diagram, and FIG. 15B is a schematic diagram of semiconductor modules constituting the circuit. The power conversion device 1 can be manufactured by mounting one semiconductor module 400, one semiconductor module 300, and two semiconductor modules 500 on a printed circuit board or the like.

The semiconductor modules 100 to 300 used in combinations 1 to 4 can be appropriately changed to Modification 1-1, Modification 1-2, Modification 2-1, Modification 2-2, and Modification 3. In addition, the present invention is not limited to the configurations described above, such as the above embodiments, modifications, and combinations, and changes or improvements that can be made by one skilled in the art based on the concept of the present invention are also within the technical scope of the present invention.

1. A semiconductor module comprising:
one lead frame;
a plurality of leads;
a plurality of semiconductor chips arranged on the lead frame; and
an insulating substrate arranged on the lead frame and including a wiring layer, wherein
the plurality of semiconductor chips includes at least a first semiconductor chip and a second semiconductor chip,
the first semiconductor chip and the second semiconductor chip each include a first main electrode and a second main electrode provided on their first and second main surfaces, respectively,
a first main surface of the insulating substrate faces the lead frame, and a second main surface of the insulating substrate includes the wiring layer provided thereon,
the first main electrode of the first semiconductor chip is electrically connected to the lead frame via a first conductive material,
the first main electrode of the second semiconductor chip is electrically connected to the wiring layer of the insulating substrate via a second conductive material, and
a first wiring electrically connecting the second main electrode of the first semiconductor chip and a first lead of the plurality of leads to each other is provided.

2. The semiconductor module according to claim 1, wherein
the plurality of leads are arranged along a first direction parallel to one side of the lead frame,
the plurality of leads extend in a direction perpendicular to the first direction, and
the first semiconductor chip and the second semiconductor chip are arranged in the first direction.

3. The semiconductor module according to claim 1, further comprising a second wiring electrically connecting the second main electrode of the second semiconductor chip and a second lead of the plurality of leads to each other.

4. The semiconductor module according to claim 3, further comprising a third semiconductor chip including a first main electrode and a second main electrode provided on a first main surface and a second main surface, respectively, wherein
the first main electrode of the third semiconductor chip is electrically connected to the lead frame via a third conductive material.

5. The semiconductor module according to claim 4, further comprising a third wiring electrically connecting the second main electrode of the third semiconductor chip and the second main electrode of the first semiconductor chip to each other.

6. The semiconductor module according to claim 1, further comprising a second wiring electrically connecting the wiring layer and a second lead of the plurality of leads to each other.

7. The semiconductor module according to claim 6, further comprising a third semiconductor chip including a first main electrode and a second main electrode provided on a first main surface and a second main surface, respectively, wherein
the first main electrode of the third semiconductor chip is electrically connected to the lead frame via a third conductive material.

8. The semiconductor module according to claim 7, further comprising a third wiring electrically connecting the second main electrode of the third semiconductor chip and the second main electrode of the first semiconductor chip to each other.

9. The semiconductor module according to claim 1, further comprising a third semiconductor chip including a first main electrode and a second main electrode provided on a first main surface and a second main surface, respectively, wherein
the first main electrode of the third semiconductor chip is electrically connected to the lead frame via a third conductive material.

10. The semiconductor module according to claim 1, wherein
the first semiconductor chip includes a transistor,
a control electrode of the transistor is arranged on the second main surface of the first semiconductor chip, and
a second wiring electrically connecting the control electrode and a third lead of the plurality of leads is provided.

11. The semiconductor module according to claim 10, wherein the control electrode is arranged on the second semiconductor chip side on the second main surface of the first semiconductor chip.

12. The semiconductor module according to claim 1, further comprising a sealing resin configured to cover the plurality of semiconductor chips and the wiring, wherein
the plurality of leads protrude from the sealing resin in a second direction perpendicular to the first direction.

13. The semiconductor module according to claim 9, wherein the second semiconductor chip and the third semiconductor chip are diodes.

14. The semiconductor module according to claim 1, wherein the first semiconductor chip is an IGBT.

15. The semiconductor module according to claim 1, wherein the first semiconductor chip is a MOSFET.

16. The semiconductor module according to claim 13, wherein
a forward voltage of the second semiconductor chip is smaller than that of the third semiconductor chip, and
a reverse recovery loss of the third semiconductor chip is smaller than that of the second semiconductor chip.
